(19) United States
(12) Patent Application Publication
(10) Pub. No.: US 2007/0201258 A1
(43) Pub. Date: Aug. 30, 2007

(54) Semiconductor memory device capable of controlling drive ability of output driver

(76) Inventor: Chang-Il Son, Yongin-si (KR)

Correspondence Address: HARNESS, DICKEY & PIERCE, P.L.C., P.O. BOX 8910, RESTON, VA, 20195, US

(21) Appl. No.: 11/650,924

(22) Filed: Jan. 9, 2007

(30) Foreign Application Priority Data
Jan. 9, 2006 (KR) 10-2006-0002295

(51) Int. Cl. G11C 5/06; H01L 29/40

(52) U.S. Cl. 365/63; 257/664

(57) ABSTRACT

An example embodiment provides a semiconductor memory device. The semiconductor memory device may include an output driver, a delay circuit and an output driver controlling circuit. The output driver may output an external output signal in response to an internal output signal. The delay circuit may receive the internal output signal to generate one or more delay signals. The output driver controlling circuit may receive the external output signal to generate control signals synchronized with the delay signals. The drive ability of the output driver is controlled by the generated control signals.

### PRIORITY STATEMENT

This U.S. non-provisional patent application claims the benefit of priority under 35 U.S.C § 119 to Korean Patent Application 2006-2295 filed on Jan. 9, 2006, the entire contents of which are hereby incorporated by reference.

### BACKGROUND

1. Field

Example embodiments relate to a semiconductor memory device. More particularly, example embodiments are related to a semiconductor memory device configured to adjust drive ability of an output driver.

2. Description of Related Art

Semiconductor memory devices are storage devices that can retain data and output the retained data as desired and/or needed. Semiconductor memory devices may be categorized into a random access memory (RAM) and a read only memory (ROM).

A ROM is a non-volatile memory that can retain data even if power supplied to the ROM is deactivated and/or interrupted. ROM devices may be further characterized as a programmable ROM (PROM), an erasable PROM (EPROM), an electrically erasable PROM (EEPROM), and a flash memory, for example.

A RAM is a volatile memory that loses data if power supplied to the RAM is deactivated and/or interrupted. RAM devices may be further characterized as dynamic RAM and static RAM, for example.

A conventional semiconductor memory device may include an output driver for outputting an internal signal to an external load. Examples of conventional output drivers are CMOS output drivers and open drain output drivers.

FIG. 1 shows a conventional semiconductor memory device with a conventional CMOS output driver. As illustrated in FIG. 1, the CMOS output driver 11 may be connected to a pad 12 to output a signal.

The conventional CMOS output driver 11 includes a PMOS transistor P1 and an NMOS transistor N1. The PMOS transistor P1 is connected between a power supply voltage terminal and an output terminal. In FIG. 1, the output terminal is the pad 12. The PMOS transistor P1 operates based on a single pull-up enable signal PEN. The NMOS transistor N1 is connected between the output terminal and a ground terminal and operates based on a single pull-down enable signal NEN.

Drive ability of the conventional CMOS output driver 11 is dependant on the sizes of the PMOS and NMOS transistors P1 and N1. Because the conventional CMOS output driver 11 is dependant on the sizes of the PMOS and NMOS transistors P1 and N1, adjusting the drive ability of the CMOS output driver 11 is difficult after the CMOS output driver is fabricated. Although an external circuit 20 connected to the pad 12 may change, it is difficult and/or impossible to change the drive ability of the conventional CMOS output driver 11. Accordingly, the conventional CMOS output driver 11 may have difficulty coping with the change of the external circuit 20 and/or may be unable to cope with the change of the external circuit 20. Stated differently, the conventional CMOS output driver 11 may have difficulty or may be unable to cope with loading of the pad 20, which may be changed by the external circuit 20. In FIG. 1, the external circuit 20 is simply illustrated by an external resistance R, an external inductance L, and an external capacitance C. In addition to the above described issues and/or problems, if the drive ability of a conventional output driver 11 deteriorates, additional time and/or costs may be needed and/or required to control timing conditions of an output signal such as a setup/hold time, for example.

### SUMMARY

Example embodiments provide a semiconductor memory device. The semiconductor memory device may include an output driver outputting an external output signal in response to an internal output signal; a delay circuit receiving the internal output signal and generating one or more delay signals; and an output driver controlling circuit receiving the external output signal and generating one or more control signals associated with the one or more delay signals to control drive ability of the output driver.

According to an example embodiment the one or more delay signals are synchronized with the one or more control signals.

Example embodiments provide a method for controlling drive ability of an output driver of a semiconductor device. The method may include generating one or more delay signals and an internal output signal; outputting an external output signal in response to the generated internal output signal; and controlling drive ability of the output driver based on the external output signal and the one or more delay signals.

### BRIEF DESCRIPTION OF THE DRAWINGS

The above and other features and advantages of example embodiments will become more apparent from a review of the following detailed description of the example embodiments and the attached drawings in which:

FIG. 1 is a circuit diagram of a conventional output driver;

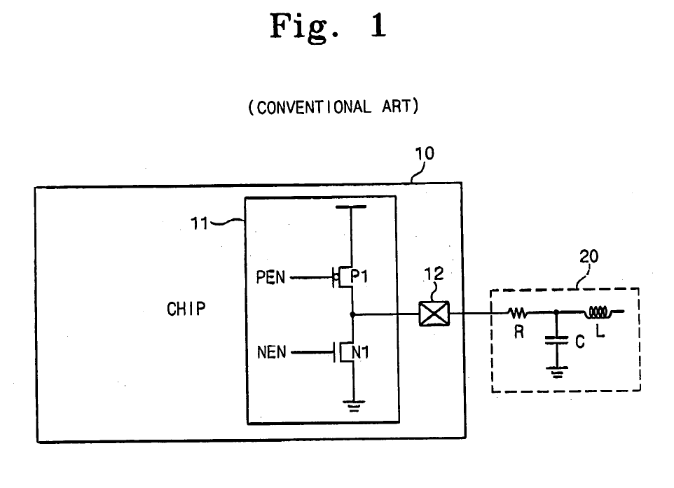

FIG. 2 is a block diagram showing an example embodiment of a semiconductor memory device;

FIG. 3 is a block diagram showing the output driver illustrated in FIG. 2;

FIG. 4 is an example truth table describing an operation of a pull-up decoder of the output driver illustrated in FIG. 3;

FIG. 5 is an example truth table describing an operation of a pull-down decoder of the output driver illustrated in FIG. 3;

FIG. 6 is an example timing diagram describing the pull-up drive ability of the output driver illustrated in FIG. 2; and

FIG. 7 is an example timing diagram describing the pull-down drive ability of the output driver illustrated in FIG. 2.

### DETAILED DESCRIPTION OF EXAMPLE EMBODIMENTS

Various example embodiments will now be described more fully with reference to the accompanying drawings. However, specific structural and functional details disclosed herein are merely representative for purposes of describing example embodiments, and one skilled in the art will appreciate that example embodiments may be embodied in many alternate forms and should not be construed as limited to only the embodiments set forth herein.

It should be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing example embodiments only and is not intended to be limiting of the example embodiments. As used herein, the singular forms “a”, “an” and “the” are intended to include the plural forms as well, unless the context clearly indicates otherwise. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which the example embodiments belong. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The example embodiments described below with respect to the drawings are provided so that this disclosure will be thorough and complete. In the drawings, like numbers refer to like elements throughout.

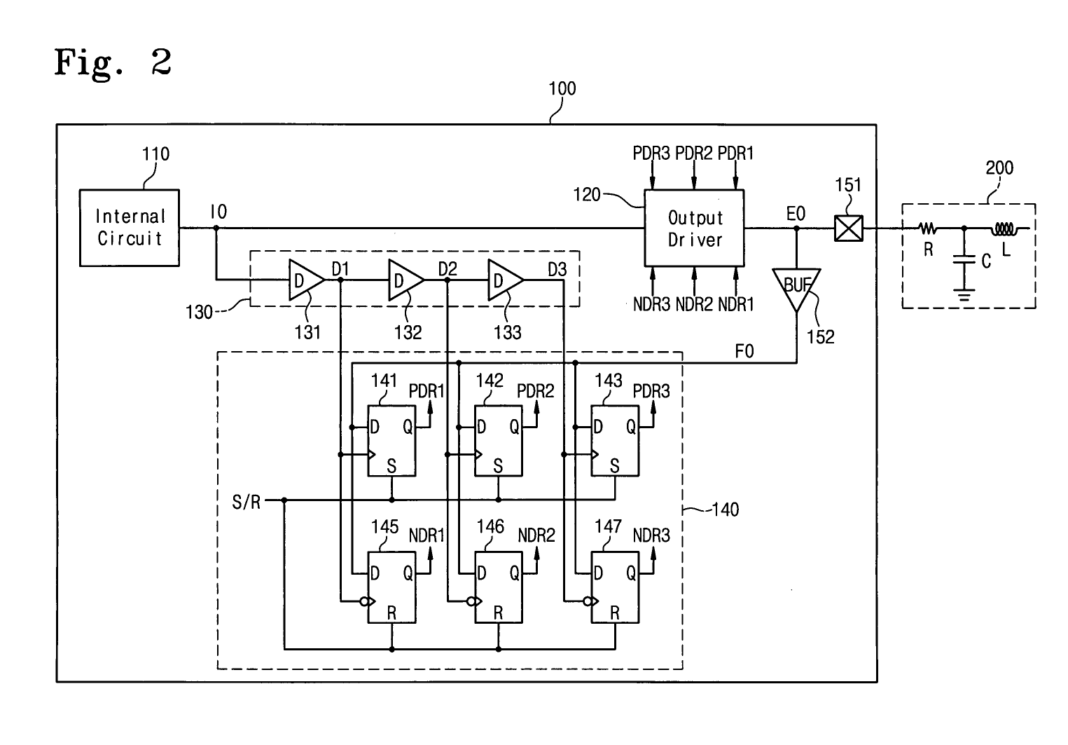

FIG. 2 is a block diagram showing an example embodiment of a semiconductor memory device.

Referring to FIG. 2, the semiconductor memory device 100 includes an internal circuit 110, an output driver 120, a delay circuit 130, and an output driver controlling circuit 140. The semiconductor memory device 100 may adjust the drive ability of the output driver 120 to cope with conditions of an external circuit 200. Herein, the conditions of the external circuit 200 are represented as an external resistance R, external inductance L, and external capacitance C.

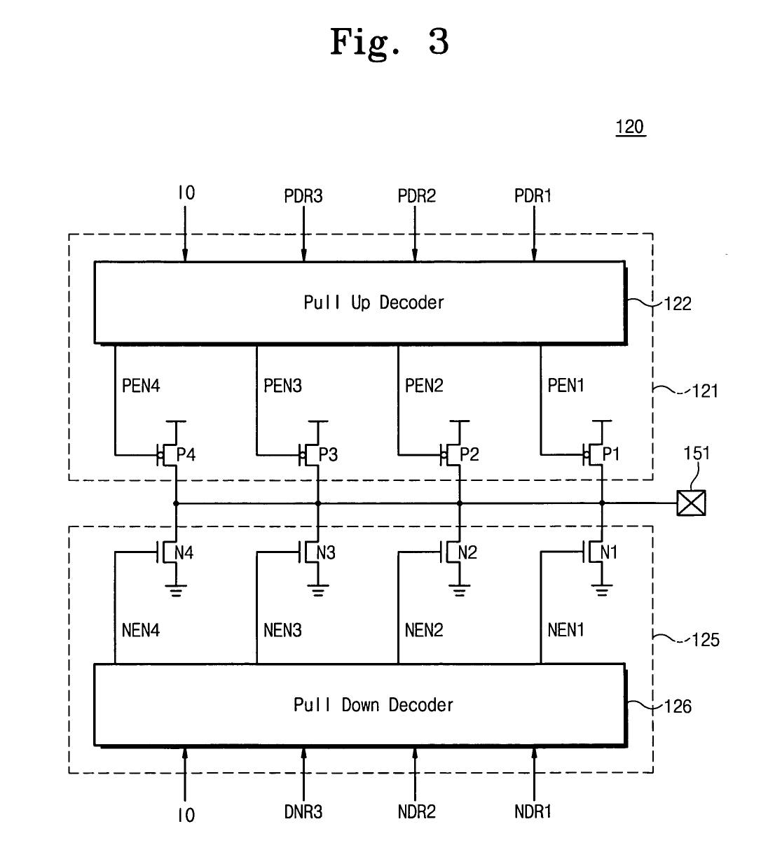

The output driver 120 may receive an internal output signal IO from the internal circuit 110. For example, in FIG. 2, the output driver 120 receives an internal output signal IO from the internal circuit 110 to output an external output signal EO via a pad 151. The output driver 120 is configured to adjust its pull-up drive ability based on one or more of the internal output signal IO and pull-up control signals PDRi (i=1-3). Further, the output driver 120 is configured to adjust its pull-down drive ability based on one or more of the internal output signal IO and pull-down control signals NDRi (i=1-3). The construction and operation of the output driver 120 is described in greater detail below with reference to FIG. 3.

The delay circuit 130 may receive the internal output signal IO to generate a plurality of delay signals. In FIG. 2, the delay circuit 130 receives the internal output signal IO and generates three delay signals D1, D2, and D3. The delay circuit 130 may include a plurality of delay elements. The example delay circuit shown in FIG. 2 includes three delay elements 131, 132, and 133 that are connected in series between an output of the internal circuit 110 and the output driver controlling circuit 140. The delay elements may be configured to have the same delay time.

As shown in the example of FIG. 2, the output driver controlling circuit 140 receives a feedback output signal FO via a buffer 152. The output driver controlling circuit 140 is configured to receive the feedback output signal FO and generate a plurality of control signals. The plurality of control signals may include the control signals PDR1 to PDR3 and NDR1 to NDR3 shown in FIG. 2, which may be synchronized with the delay signals D1, D2, and D3.

The output driver controlling circuit 140 may include a plurality of pull-up and pull-down registers. Each of the plurality of pull-up and pull-down registers may provide a control signal according to an example embodiment.

The example output driver controlling circuit 140 in FIG. 2 includes first to third pull-up registers 141 to 143 and first to third pull-down registers 145 to 147. The first to third pull-up registers 141 to 143 receive the feedback output signal FO and output first to third pull-up control signals PDR1 to PDR3 according to an example embodiment. The first to third pull-up control signals PDR1 to PDR3 may be synchronized with the first to third delay signals D1 to D3, respectively. The first to third pull-down registers 145 to 147 receive the feedback output signal FO and output first to third pull-down control signals NDR1 to NDR3, respectively. The first to third pull-down control signals NDR1 to NDR3 may be synchronized with the first to third delay signals D1 to D3, respectively. According to the example in FIG. 2, the first to third pull-up control signals PDR1 to PDR3 are signals for controlling the pull-up drive ability of the output driver 120 and the first to third pull-down control signals NDR1 to NDR3 are signals for controlling the pull-down drive ability of the output driver 120.

Each of the first to third pull-up registers 141 to 143 may be reset to a set state, e.g., logic “1”, in response a reset signal S/R, and each of the first to third pull-down registers 145 to 147 may be reset to a reset state, e.g., logic “0” in response the reset signal S/R. Herein, the reset signal S/R may be generated in hardware at power-up or in software by an internal operation, for example.

FIG. 3 is an example block diagram of an output driver illustrated in FIG. 2. As shown in FIG. 3, the output driver 120 may include a pull-up driver 121 and a pull-down driver 125.

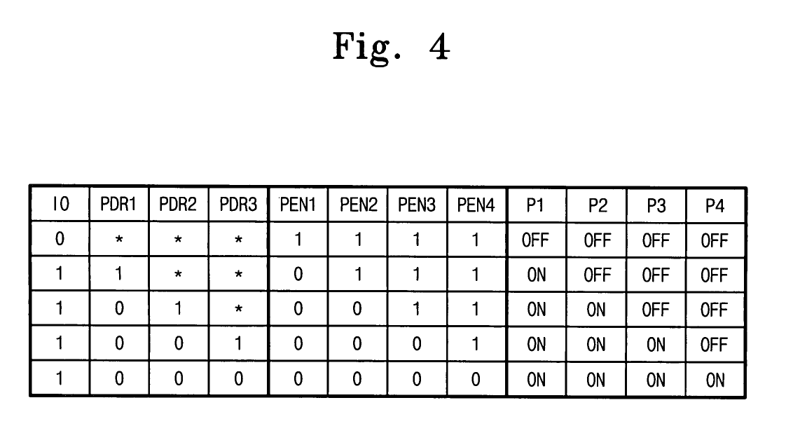

The pull-up driver 121 is configured to adjust the pull-up drive ability of the output driver 120 in response to one or more of an internal output signal IO and first to third pull-up control signals PDR1 to PDR3. The pull-up driver 121 may include a plurality of pull-up transistors and a pull-up decoder. For example, the pull-up driver 121 shown in FIG. 3 includes first to fourth pull-up transistors P1 to P4 and a pull-up decoder 122. The pull-up transistors P1 to P4 may be connected in parallel between a power supply voltage terminal and a pad 151, which may correspond to an output terminal. In one example embodiment, the pull-up transistors P1 to P4 are PMOS transistors. The pull-up decoder 122 may decode the internal output signal IO and the first to third pull-up control signals PDR1 to PDR3 and may generate first to fourth pull-up enable signals PEN1 to PEN4 for controlling the first to fourth pull-up transistors P1 to P4, respectively, which is described in greater detail below with respect to FIG. 4.

Referring to the example shown in FIG. 4, if the internal output signal IO is at a low level indicated as a “0”, the pull-up decoder 122 outputs the first to fourth pull-up enable signals having a high level indicated as a “1”, regardless of the first to third pull-up control signals PDR1 to PDR3. This deactivates the first to fourth pull-up transistors P1 to P4 as shown by the “off” in FIG. 4. The pull-up decoder 122 activates the first pull-up transistor P1 if the internal output signal IO and the first pull-up control signal PDR1 each have a high level. Further, the pull-up decoder 122 activates the first and second pull-up transistors P1 and P2 if the internal output signal IO and the second pull-up control signal PDR2 each have a high level. Still further, each of the first to third pull-up transistors P1 to P3 are activated by the pull-up decoder 122 if the internal output signal IO and the third pull-up control signal PDR1 each have a high level. Lastly, in the example of FIG. 4, if the first to third pull-up control signals PDR1 to PDR3 correspond to a low level, the first to fourth pull-up transistors P1 to P4 are activated by the pull-up decoder 122.

According to the above-described manner, the pull-up drive ability of the output driver 120 may be adjusted by the pull-up driver 121 operating based on a combination of the internal output signal IO and the first to third pull-up control signals PDR1 to PDR3.

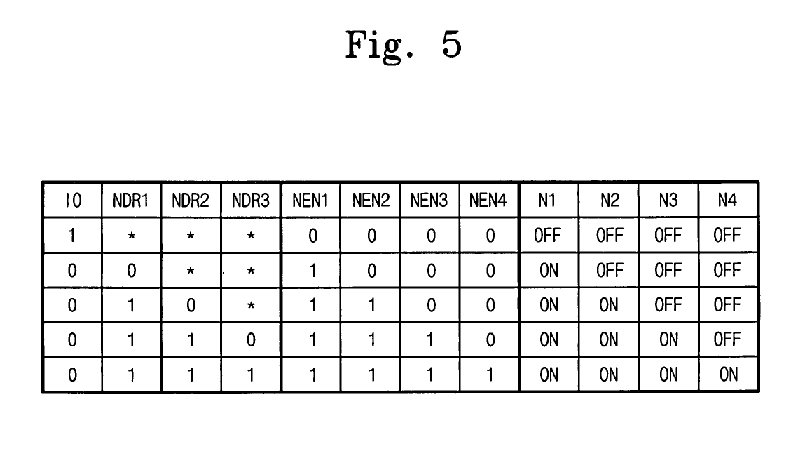

Returning to FIG. 3, the pull-down driver 125 is configured to adjust the pull-up drive ability of the output driver 120 in response to one or more of the internal output signal IO and first to third pull-down control signals NDR1 to NDR3. The pull-down driver 125 may include a plurality of pull-down transistors and a pull-down decoder. For example, the pull-down driver 125 shown in the example of FIG. 3 includes first to fourth pull-down transistors N1 to N4 and a pull-down decoder 126. The pull-down transistors N1 to N4 may be connected in parallel between the pad 151 and a ground voltage terminal. In one example embodiment, the pull-down transistors N1 to N4 are NMOS transistors. The pull-down decoder 126 may decode the internal output signal IO and the first to third pull-down control signals NDR1 to NDR3 and may generate first to fourth pull-down enable signals NEN1 to NEN4 for controlling the first to fourth pull-down transistors N1 to N4, respectively, which is described in greater detail below with reference to FIG. 5.

Referring to the example shown in FIG. 5, if the internal output signal IO is at a high level indicated as a “1”, the pull-down decoder 126 outputs the first to fourth pull-down enable signals having a low level indicated as a “0” regardless of the first to third pull-down control signals NDR1 to NDR3. This deactivates the first to fourth pull-down transistors N1 to N4 as shown by the “off” in FIG. 5. The pull-down decoder 126 activates the first pull-down transistor N1 if the internal output signal IO and the first pull-down control signal NDR1 each have a low level. Further, the pull-down decoder 126 activates the first and second pull-down transistors N1 and N2 if the internal output signal IO and the second pull-down control signal NDR2 each have a low level. Still further, each of the first to third pull-down transistors N1 to N3 are activated by the pull-down decoder 126 if the internal output signal IO and the third pull-down control signal NDR1 each have a low level. Lastly, in the example shown in FIG. 5, if the first to third pull-down control signals NDR1 to NDR3 correspond to a high level, the first to fourth pull-down transistors N1 to N4 are activated by the pull-down decoder 126.

According to the above-described manner, the pull-down drive ability of the output driver 120 may be adjusted through the pull-down driver 121 that operates based on a combination of the internal output signal IO and the first to third pull-down control signals NDR1 to NDR3.

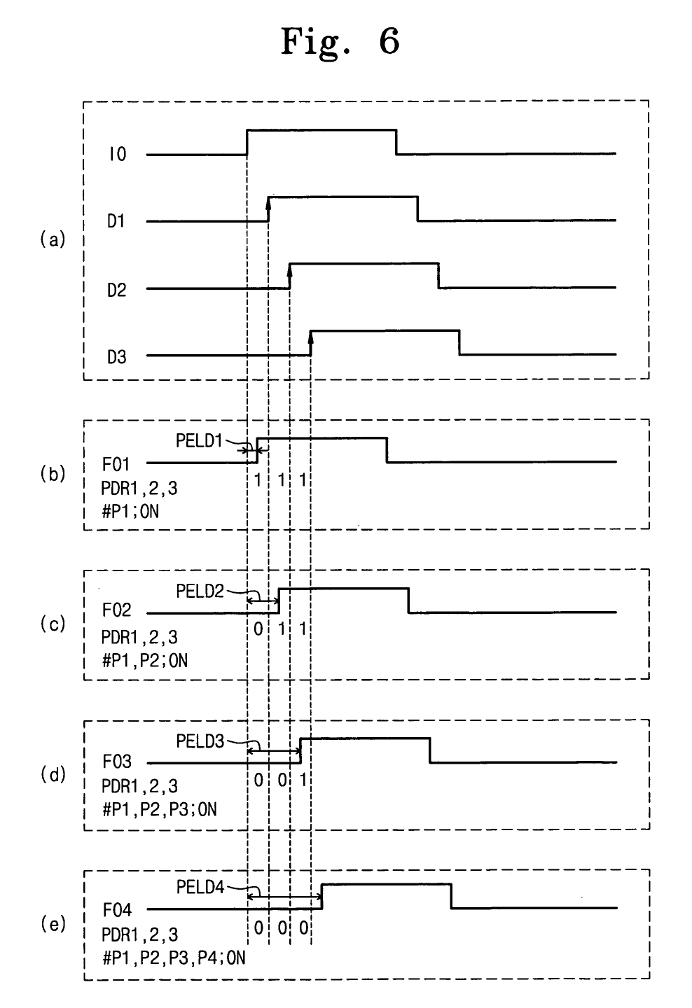

FIG. 6 is an example timing diagram for describing a pull-up drive ability of an output driver illustrated in FIG. 2. FIG. 6(a) shows the internal output signal IO and the first to third delay signals D1 to D3, and FIGS. 6(b)-6(e) show a combination of the first to third pull-up control signals PDR1 to PDR3 based on variations of the feedback output signal FO due to a change in the external loading. For example, PELDi (i=1-4) indicates a delay time between a low-to-high transition of the internal output signal IO and a low-to-high transition of the feedback output signal FO. As illustrated in FIGS. 6(b)-6(e), when a delay time increases/decreases due to loading change of the external circuit, the first to third pull-up control signals PDR1 to PDR3 are generated such that the first to fourth pull-up transistors P1 to P4 are sequentially activated/deactivated. Accordingly, as the number of activated/deativated pull-up transistors increases/decreases automatically, the pull-up drive ability of the output driver 120 may be improved according to an example embodiment.

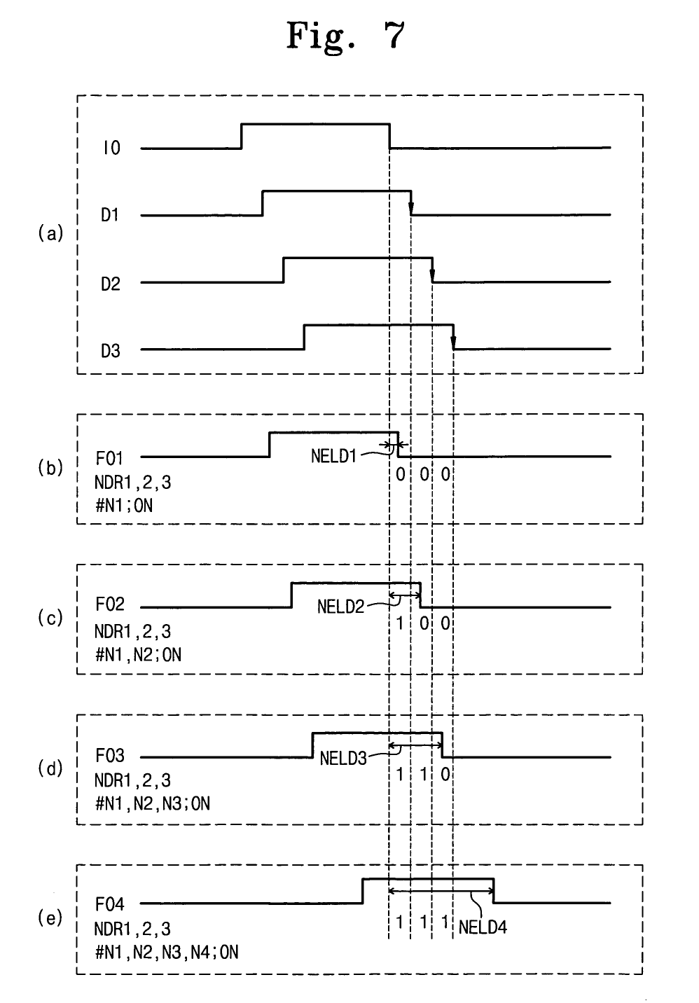

FIG. 7 is an example timing diagram for describing a pull-up drive ability of an output driver illustrated in FIG. 2. FIG. 7(a) shows the internal output signal IO and the first to third delay signals D1 to D3, and FIGS. 7(b)-7(e) show a combination of the first to third pull-down control signals NDR1 to NDR3 based on variations of the feedback output signal FO due to change of external loading. For example, NELDi (i=1-4) indicates a delay time between a high-to-low transition of the internal output signal IO and a high-to-low transition of the feedback output signal FO. As illustrated in FIGS. 7(b)-7(e), when a delay time increases/decreases due to loading change of the external circuit, the first to third pull-down control signals NDR1 to NDR3 are generated such that the first to fourth pull-down transistors N1 to N4 are sequentially activated/deactivated. Accordingly, as the number of activated/deactivated pull-down transistors increases/decreases automatically, the pull-down drive ability of the output driver 120 may be improved according to an example embodiment.

As set forth above, an example embodiment of a semiconductor memory device is configured to receive as a feedback output signal an external output signal output via a pad and to generate pull-up/down control signals synchronized with delayed versions of an internal output signal. An example embodiment of a semiconductor memory device is configured to decode the internal output signal and the pull-up/down control signals to adjust the drive ability of the output driver. Accordingly, it is possible to automatically adjust the drive ability of the output driver so as to be suitable for external conditions of the semiconductor memory device such as external resistance, external inductance and external capacitance.

Although example embodiments have been described in connection with the accompanying drawings, example embodiments are not limited thereto. It will be apparent to those skilled in the art that various substitutions, modifications and changes may be thereto without departing from the scope and spirit of the invention as defined by the following claims.

What is claimed is:

1. A semiconductor memory device comprising:
an output driver outputting an external output signal in response to an internal output signal;
a delay circuit receiving the internal output signal and generating at least one delay signal; and
an output driver controlling circuit receiving the external output signal and generating at least one control signal associated with the at least one delay signal to control drive ability of the output driver.

2. The semiconductor device of claim 1, wherein the at least one control signal is synchronized with the at least one delay signal.

3. The semiconductor memory device of claim 1, wherein the delay circuit comprises a plurality of delay elements which are connected in series, each of the plurality of delay elements outputting a delay signal.

4. The semiconductor memory device of claim 1, wherein the output driver controlling circuit comprises:
a pull-up register receiving the at least one delay signal and the external output signal to generate at least one pull-up control signal controlling a pull-up drive ability of the output driver; and
a pull-down register receiving the at least one delay signal and the external output signal to generate at least one pull-down control signal controlling a pull-down drive ability of the output driver.

5. The semiconductor memory device of claim 4, wherein the pull-up register is reset to a set state at activation.

6. The semiconductor memory device of claim 4, wherein the pull-down register is reset to a reset state at activation.

7. The semiconductor memory device of claim 4, wherein the output driver comprises:
a pull-up driver adjusting the pull-up drive ability of the output driver based on the internal output signal and the pull-up control signal; and
a pull-down driver adjusting the pull-down drive ability of the output driver based on the internal output signal and the pull-down control signal.

8. The semiconductor memory device of claim 7, wherein the pull-up driver comprises:
a plurality of pull-up transistors connected in parallel between a power supply voltage terminal and an output terminal of the output driver; and
a pull-up decoder decoding the internal output signal and the pull-up control signal to generate signals controlling the plurality of pull-up transistors.

9. The semiconductor memory device of claim 8, wherein the plurality of pull-up transistors include a plurality of PMOS transistors.

10. The semiconductor memory device of claim 7, wherein the pull-down driver comprises:
a plurality of pull-down transistors connected in parallel between an output terminal of the output driver and a ground voltage terminal; and
a pull-down decoder decoding the internal output signal and the pull-down control signal to generate signals controlling the plurality of pull-down transistors.

11. The semiconductor memory device of claim 10, wherein the plurality of pull-down transistors include a plurality of NMOS transistors.

12. The semiconductor memory device of claim 4, wherein the output driver comprises:
a plurality of pull-up transistors connected in parallel between a power supply voltage terminal and an output terminal of the output driver;
a plurality of pull-down transistors connected in parallel between the output terminal of the output driver and a ground voltage terminal;
a pull-up decoder decoding the internal output signal and the pull-up control signal to generate signals controlling the plurality of pull-up transistors; and
a pull-down decoder decoding the internal output signal and the pull-down control signal to generate signals controlling the plurality of pull-down transistors.

13. A method for controlling drive ability of an output driver of a semiconductor device, the method comprising:
generating at least one delay signal and an internal output signal;
outputting an external output signal in response to the generated internal output signal; and
controlling drive ability of the output driver based on the external output signal and the at least one delay signal.

14. The method of claim 13, wherein controlling drive ability of the output driver comprises:
receiving the external output signal and the at least one delay signal;
generating at least one control signal associated with the at least one delay signal; and
providing the at least one control signal to the output driver.

15. The method of claim 14, wherein the at least one control signal is synchronized with the at least one delay signal.

16. The method of claim 14, wherein the at least one control signal varies depending on an external load connected to the output driver.
